(19) United States
(12) Patent Application Publication
(10) Pub. No.: US 2011/0123927 A1
(43) Pub. Date: May 26, 2011

(54) PHOTOSENSITIVE RESIN COMPOSITION CONTAINING POLYIMIDE RESIN AND NOVOLAK RESIN

(75) Inventors: Chan Hyo Park, Daejeon (KR); Hye In Shin, Seoul (KR); Hye Ran Seong, Daejeon (KR); Kyung Jun Kim, Daejeon (KR); Dong Hyun Oh, Daejeon (KR)

(73) Assignee: LG CHEM, LTD., Seoul (KR)

(21) Appl. No.: 12/994,010

(22) PCT Filed: May 20, 2009
(86) PCT No.: PCT/KR09/02646

§ 371 Date: Feb. 10, 2011

(30) Foreign Application Priority Data
May 22, 2008 (KR) 10-2008-0047702

(51) Int. Cl. G03F 7/004; G03F 7/20; B05D 3/02; B05D 7/24; B05D 7/14

(52) U.S. Cl. 430/270.1; 430/325; 427/385.5; 427/388.1

(57) ABSTRACT

A photosensitive resin composition is provided. The photosensitive resin composition comprises a) an alkali-soluble polyimide resin, b) an alkali-soluble novolak resin, c) a photosensitizer, and d) an organic solvent. The photosensitive resin composition is resistant to heat and can be used to form a pattern whose lateral angles are easily controllable. A large difference in developability between exposed and unexposed portions of the photosensitive resin composition is caused when patterning. The photosensitive resin composition is advantageous in terms of sensitivity, resolution, heat resistance and adhesiveness. Particularly, the lateral angles of the pattern can be easily controlled by varying the contents of the alkali-soluble resins. Therefore, the photosensitive resin composition is useful in the formation of an insulating film pattern of an organic light emitting diode (OLED).

### TECHNICAL FIELD

The present invention relates to a photosensitive resin composition comprising an alkali-soluble polyimide resin, an alkali-soluble novolak resin, a photosensitizer and an organic solvent. More specifically, the present invention relates to a photosensitive resin composition for use in the formation of an insulating film pattern of an electronic device such as an organic light emitting diode (OLED).

### BACKGROUND ART

Polyimide resins are stable even at processing temperatures as high as 200° C. due to their good heat resistance, and have the advantages of high mechanical strength and low dielectric constant. Polyimide resins produce highly planar surfaces upon coating and contain small amounts of impurities that negatively affect the reliability of devices. Polyimide resins have the advantage that fine patterns are easy to realize. Due to these advantages, polyimide resins have attracted attention as materials for insulating films of OLEDs.

Numerous photosensitive polyimide resins for use in the formation of positive patterns with high contrast between exposed and unexposed portions thereof have been disclosed in many patent publications. For example, Japanese Unexamined Patent Publication Nos. 52-13315 and 62-135824 describe polyamic acid resins as polyimide precursors, Japanese Unexamined Patent Publication No. 64-60630 describes a soluble polyimide having hydroxyl groups, and Japanese Unexamined Patent Publication No. 60-37550 describes a polyimide resin prepared by esterifying photosensitive groups of a polyimide precursor. Further, Japanese Unexamined Patent Publication Nos. 7-33874 and 7-134414 describe chemically amplified compositions, each of which comprises and a photoacid generator and a resin prepared by replacing carboxyl groups of a polyamic acid with acid-dissociable functional groups. However, these known resins do not interact with photosensitizers to a level sufficient to form high-resolution patterns. This insufficient interaction results in a small difference in dissolution rate between exposed and unexposed portions of the resins, requires the addition of large amounts of photosensitizers, and makes it difficult to control the lateral angles of patterns for OLEDs.

Novolak resins have high contrast between exposed and unexposed portions thereof due to their good interaction with photosensitizers and are advantageous in terms of adhesion to substrates and pattern accuracy, in comparison with other resins. Based on these advantages, since the 1970's, novolak resins have been put into practice for the formation of positive photosensitive metal etching pattern in general electronic circuits. Novolak resins begin to flow around 160° C. Accordingly, novolak resins are usually used below 160° C., which is a temperature sufficient to prepare resin compositions for the transfer of metal patterns in general electronic circuits. Taking into consideration the fact that the maximum processing temperature required in the related art is at least 200° C., patterns formed using photosensitive novolak resin compositions cannot be maintained at temperatures higher than 160° C. due to the poor heat resistance of the novolak resins.

In view of this situation, the use of polyimide resins is considered. A typical polyimide resin has a glass transition temperature of 300° C. or greater, which guarantees sufficient heat resistance of the polyimide resin at processing temperatures of at least 200° C. As already mentioned above, the lateral angles of a pattern required to maintain the light emitting performance of an organic electroluminescent (EL) part of an OLED should be as low as possible in view of the structural characteristics of an insulating film in a circuit of the OLED. However, sufficiently low lateral angles of a typical pattern formed using a photosensitive polyimide resin composition cannot be guaranteed so long as the glass transition temperature of the polyimide resin is not controlled by structural modification. Thus, there is a need to mix a novolak resin having relatively low heat resistance with a photosensitive polyimide resin composition in order to achieve the advantages of both resins.

### DISCLOSURE

### Technical Problem

An object of the present invention is to provide a photosensitive resin composition for use in the formation of a pattern whose lateral angles are easily controllable, which is prepared by mixing a photosensitive polyimide composition having good heat resistance even at a temperature of at least 200° C. with a novolak resin that has poor heat resistance as compared to the polyimide but shows high-resolution pattern performance due to its good interaction with a photosensitizer and excellent flow characteristics after post-baking at a temperature of at least 200° C. and is advantageous in terms of adhesiveness and water repellency, in a certain ratio.

### Technical Solution

According to an aspect of the present invention, there is provided a photosensitive resin composition which comprises a) 3 to 30 parts by weight of an alkali-soluble polyimide resin, b) 3 to 30 parts by weight of an alkali-soluble novolak resin, c) 1 to 10 parts by weight of a photosensitizer, and d) 59 to 93 parts by weight of an organic solvent.

According to another aspect of the present invention, there is provided a method for forming an organic insulating film, the method comprising coating the photosensitive resin composition on a substrate and curing the coated composition.

According to another aspect of the present invention, there is provided an organic insulating film formed by the method.

According to another aspect of the present invention, there is provided a method for forming a photosensitive pattern, the method comprising a) coating the photosensitive resin composition on a substrate and pre-baking the coated composition to form an organic insulating film, and b) selectively exposing and developing the organic insulating film, followed by post-baking.

According to yet another aspect of the present invention, there is provided an electronic device comprising the organic insulating film or the photosensitive pattern.

### Advantageous Effects

The photosensitive resin composition of the present invention can be used to form a photosensitive pattern whose lateral angles are easily controllable. The photosensitive resin composition of the present invention is particularly useful in the fabrication of an OLED that requires a pattern having low lateral angles.

In addition, the photosensitive resin composition of the present invention can be used to form a pattern whose lateral angles can be controlled to a low level, preferably less than 20°, while maintaining its ability to form a pattern. Therefore, the use of the photosensitive resin composition according to the present invention is advantageous in increasing the efficiency of an electronic device without causing electrical short circuits in the electronic device.

Furthermore, the structural affinity of the novolak resin as a binder for the photosensitizer leads to a large difference in developability and a high resolution between exposed and unexposed portions of the photosensitive resin composition according to the present invention in the fabrication of an electronic device. Moreover, an accurate critical dimension (CD) of a photoresist pattern can be achieved even after post-baking.

### DESCRIPTION OF DRAWINGS

FIG. 1 is a diagram illustrating an insulating film of an OLED, which is formed using a photosensitive resin composition of the present invention.

FIG. 2 shows cross-sectional scanning electron microscopy (SEM) images of a lateral side of a pattern, which was formed using a photosensitive resin composition prepared in Example 1, taken before and after post-baking.

FIG. 3 shows cross-sectional scanning electron microscopy (SEM) images of a lateral side of a pattern, which was formed using a photosensitive polyimide resin composition prepared in Comparative Example 1, taken before and after post-baking.

### BEST MODE

The present invention will now be described in detail.

The present invention provides a photosensitive resin composition comprising

a) 3 to 30 parts by weight of an alkali-soluble polyimide resin, b) 3 to 30 parts by weight of an alkali-soluble novolak resin, c) 1 to 10 parts by weight of a photosensitizer, and d) 59 to 93 parts by weight of an organic solvent.

The alkali-soluble polyimide resin a) is represented by Formula 1:

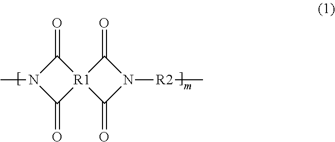

wherein m is an integer from 3 to 10,000, R¹ is a tetravalent organic group, and R² is a divalent organic group, with the proviso that 5 to 100 mol % of R² is fluorinated.

The alkali-soluble polyimide resin a) has at least one reactive end-capping group at one or both ends of the polymer chain.

No particular limitation is imposed on the method for preparing the soluble polyimide of Formula 1. The polyimide is prepared by the reaction of an acid anhydride containing R¹ with a diamine containing R². The acid anhydride does not require any particular structure. The acid anhydride may be used alone or in combination with one or two other acid anhydrides.

Specific examples of the acid anhydride include aromatic tetracarboxylic anhydrides, such as pyromellitic anhydride, 3,3′,4,4′-biphenyltetracarboxylic dianhydride, 3,3′,4,4′-benzophenonetetracarboxylic dianhydride, 3,3′,4,4′-diphenyl ether tetracarboxylic dianhydride, 3,3′,4,4′-diphenylsulfonetetracarboxylic dianhydride and 2,2-bis(3,4-dicarboxyphenyl)hexafluoroisopropylidene dianhydride. 3,3′,4,4′-Diphenyltetracarboxylic dianhydride, 3,3′,4,4′-benzophenonetetracarboxylic dianhydride, 4,4′-(hexafluoroisopropylidene)diphthalic anhydride and 3,3′,4,4′-diphenylsulfonetetracarboxylic dianhydride are preferred in terms of solubility.

Other examples include: alicyclic tetracarboxylic dianhydrides, such as 1,2,3,4-cyclobutanetetracarboxylic dianhydride, 1,2-dimethyl-1,2,3,4-cyclobutanetetracarboxylic dianhydride, 1,2,3,4-tetramethyl-1,2,3,4-cyclobutanetetracarboxylic dianhydride, 1,2,3,4-cyclopentanetetracarboxylic dianhydride, 1,2,4,5-cyclohexanetetracarboxylic dianhydride, 3,4-dicarboxy-1,2,3,4-tetrahydro-1-naphthalenesuccinic dianhydride, 5-(2,5-dioxotetrahydrofuryl)-3-methyl-3-cyclohexene-1,2-dicarboxylic dianhydride, 2,3,5-tricarboxy-2-cyclopentaneacetic dianhydride, bicyclo[2.2.2]oct-7-ene-2,3,5,6-tetracarboxylic dianhydride, 2,3,4,5-tetrahydrofurantetracarboxylic dianhydride and 3,5,6-tricarboxy-2-norbornane acetic dianhydride; and aliphatic tetracarboxylic dianhydrides, such as 1,2,3,4-butanetetracarboxylic dianhydride.

The diamine may be used alone or in combination with one or two other diamines

Specific examples of the diamine include: fluorinated amines, such as 2,2′-bis(trifluoromethyl)benzidine, 2,6,2′,6′-tetrakis(trifluoromethyl)benzidine, 2,2-bis[4-(3-aminophenoxy)phenyl]hexafluoropropane, 2,2-bis[4-(4-aminophenoxy)phenyl]hexafluoropropane, 2,2-bis(4-anilino)hexafluoropropane, 2,2-bis(3-anilino)hexafluoropropane and 2,2-bis(3-amino-4-toluyl)hexafluoropropane; aromatic diamines, such as p-phenylenediamine, m-phenylenediamine, 2,4,6-trimethyl-1,3-phenylenediamine, 2,3,5,6-tetramethyl-1,4-phenylenediamine, 4,4′-diaminodiphenyl ether, 3,4′-diaminodiphenyl ether, 3,3′-diaminodiphenyl ether, 4,4′-diaminodiphenyl sulfide, 4,4′-diaminodiphenylmethane, 3,4′-diaminodiphenylmethane, 3,3′-diaminodiphenylmethane, 4,4′-methylene-bis(2-methylaniline), 4,4′-methylene-bis(2,6-dimethylaniline), 4,4′-methylene-bis(2,6-diethylaniline), 4,4′-methylene-bis(2-isopropyl-6-methylaniline), 4,4′-methylene-bis(2,6-diisopropylaniline), 4,4′-diaminodiphenylsulfone, 3,3′-diaminodiphenylsulfone, benzidine, o-toluidine, m-toluidine, 3,3′,5,5′-tetramethylbenzidine, 2,2′-bis(trifluoromethyl)benzidine, 1,4-bis(4-aminophenoxy)benzene, 1,3-bis(4-aminophenoxy)benzene, 1,3-bis(3-aminophenoxy)benzene, bis [4-(4-aminophenoxy)phenyl]sulfone, bis[4-(3-aminophenoxy)phenyl]sulfone, 2,2-bis[4-(4-aminophenoxy)phenyl]propane and 2,2-bis[4-(3-aminophenoxy)phenyl]propane; and aliphatic diamines, such as 1,6-hexanediamine, 1,4-cyclohexanediamine, 1,3-cyclohexanediamine, 1,4-bis(aminomethyl)cyclohexane, 1,3-bis(aminomethyl)cyclohexane, 4,4′-diaminodicyclohexylmethane and 4,4′-diamino-3,3′-dimethylcyclohexylmethane.

R² in Formula 1 may have one or more acid groups, which may be the same or different. That is, the diamine constituting R² in Formula 1 may one or more acid groups may be used.

As the acid groups, there may be exemplified phenolic hydroxyl groups, carboxylic acid groups, sulfonamide groups and sulfonic acid groups. Carboxylic acid groups and phenolic hydroxyl groups are the most general acid groups of positive type photosensitive polymers. A polyimide having no acid groups is soluble in an organic solvent but is not dissolved in an alkaline developing solution. As in the present invention, the introduction of the acid groups increases the affinity of the polyimide for an alkaline developing solution. The presence of the acid groups to some degree in the polyimide leads to an increase in the dissolution rate of a film formed using the photosensitive resin composition of the present invention in an alkaline developing solution, thus shortening the time required to develop the photosensitive resin composition.

The soluble polyimide of Formula 1 is preferably dissolved at a rate of 0.1 μm/min or less in an aqueous solution of tetramethylammonium hydroxide (2.38 wt %) at 23° C. A dissolution rate higher than 0.1 μm/min results in deterioration of contrast and sensitivity.

The diamine having one or more acid groups may be fluorinated. That is, R² may be a divalent organic group having one or more acid groups and one or more fluorine atoms. Therefore, the diamine benefits from the presence of both fluorine atoms and acid groups.

Examples of the fluorinated diamine having acid groups include: diamines having phenolic hydroxyl groups, such as 2,2-bis(3-amino-4-hydroxyphenyl)hexafluoropropane, 2,2-bis(4-amino-3-hydroxyphenyl)hexafluoropropane, 2,2-bis(4-amino-3,5-dihydroxyphenyl)hexafluoropropane and 2,2-bis[4-(3-amino-4-hydroxyphenoxy)phenyl]hexafluoropropane; and diamines having one or more carboxyl groups, such as 2,2-bis[4-(4-amino-3-carboxyphenoxy)phenyl]hexafluoropropane. R² having both acid groups and fluorine atoms is a divalent organic group constituting each of the fluorinated diamines

Examples of the non-fluorinated diamine having acid groups include: diamines having phenolic hydroxyl groups, such as 2,4-diaminophenol, 3,5-diaminophenol, 2,5-diaminophenol, 4,6-diaminoresorcinol, 2,5-diaminohydroquinone, bis(3-amino-4-hydroxyphenyl)ether, bis(4-amino-3-hydroxyphenyl)ether, bis(4-amino-3,5-dihydroxyphenyl)ether, bis(3-amino-4-hydroxyphenyl)methane, bis(4-amino-3-hydroxyphenyl)methane, bis(4-amino-3,5-dihydroxyphenyl)methane, bis(3-amino-4-hydroxyphenyl)sulfone, bis(4-amino-3-hydroxyphenyl)sulfone, bis(4-amino-3,5-dihydroxyphenyl)sulfone, 4,4′-diamino-3,3′-dihydroxybiphenyl, 4,4′-diamino-3,3′-dihydroxy-5,5′-dimethylbiphenyl, 4,4′-diamino-3,3′-dihydroxy-5,5′-dimethoxybiphenyl, 1,4′-bis(3-amino-4-hydroxyphenoxy)benzene, 1,3-bis(3-amino-4-hydroxyphenoxy)benzene, 1,4-bis(4-amino-3-hydroxyphenoxy)benzene, 1,3-bis(4-amino-3-hydroxyphenoxy)benzene, bis[4-(3-amino-4-hydroxyphenoxy)phenyl]sulfone and bis[4-(3-amino-4-hydroxyphenoxy)phenyl]propane; and diamines having one or more carboxyl groups, such as 2,4-diaminobenzoic acid, 2,5-diaminobenzoic acid, 3,5-diaminobenzoic acid, 4,6-diamino-1,3-benzenedicarboxylic acid, 2,5-diamino-1,4-benzenedicarboxylic acid, bis(4-amino-3-carboxyphenyl)ether, bis(4-amino-3,5-dicarboxyphenyl)ether, bis(4-amino-3-carboxyphenyl)sulfone, bis(4-amino-3,5-dicarboxyphenyl)sulfone, 4,4′-diamino-3,3′-dicarboxybiphenyl, 4,4′-diamino-3,3′-dicarboxy-5,5′-dimethylbiphenyl, 4,4′-diamino-3,3′-dicarboxy-5,5′-dimethoxybiphenyl, 1,4-bis(4-amino-3-carboxyphenoxy)benzene, 1,3-bis(4-amino-3-carboxyphenoxy)benzene, bis[4-(4-amino-3-carboxyphenoxy)phenyl]sulfone and bis[4-(4-amino-3-carboxyphenoxy)phenyl]propane. R² having acid groups but no fluorine atom is a divalent organic group constituting each of the non-fluorinated diamines

The diamines having acid groups may be used alone or in combination with one or two other diamines

The soluble polyimide of Formula 1 is preferably prepared by reacting a tetracarboxylic dianhydride, a diamine and a monomer, which is a source for providing a reactive end-capping group, in a polar solvent such as N-methyl-2-pyrrolidone (NMP) in the temperature range of 0 to 10° C. for at least 4 hr to synthesize a corresponding polyamic acid, and thermally curing the polyamic acid at a temperature of 120 to 180° C. for 2 to 4 hr.

The polyimide resin may have or have not at least one reactive end-capping group at one or both ends of the polymer chain. There is no particular limitation on the kind of the reactive end-capping group.

The monomer added to provide a reactive end-capping group to the polyamic acid may be a monoamine or monoanhydride compound having at least one carbon-carbon double bond. By the addition of the monomer, the molecular weight of the polyamic acid can be controlled to a desired range and the viscosity of the final resin composition can be reduced. In addition, the adjacent end-capping groups of the polyimide resin are crosslinked during curing after patterning to bring about a great increase in the molecular weight of a film formed using the photosensitive resin composition of the present invention, contributing to a marked improvement in the physical properties of the film.

The novolak resin b) is soluble in an alkaline developing solution and can be added to the polyimide resin to make the final resin composition flowable. This flowability reduces the lateral angles of a pattern formed using the photosensitive resin composition. However, taking into consideration heat resistance and the ability to form a pattern, the novolak resin is preferably added in an amount of 3 to 30 parts by weight.

The novolak resin b) has alkali-soluble groups and is prepared by condensation of a phenol and an aldehyde. Examples of suitable phenols include phenol, 4-t-butylphenol, 4-t-octylphenol, 2-ethylphenol, 3-ethylphenol, 4-ethylphenol, o-cresol, m-cresol, p-cresol, 2,5-xylenol, 3,4-xylenol, 3,5-xylenol, 2,3,5-trimethylphenol, 3-methyl-6-t-butylphenol, 2-naphthol, 1,3-dihydroxynaphthalene and bisphenol A. These phenols may be used alone or as a mixture of two or more thereof. Examples of suitable aldehydes include formaldehyde, paraformaldehyde, acetaldehyde, benzaldehyde and phenylaldehyde. These aldehydes may be used alone or as a mixture of two or more thereof. A catalyst may be used for the condensation of the phenol and the aldehyde. As the catalyst, there may be used, for example: an organic acid, such as oxalic acid, p-toluenesulfonic acid or trichloroacetic acid; an inorganic acid, such as sulfuric acid, hydrochloric acid or phosphoric acid; or a metal salt, such as zinc chloride, aluminum chloride, magnesium acetate or zinc acetate. The weight average molecular weight of the novolak resin is preferably in the range of 2,500 to 15,000 on a polystyrene basis. If the novolak resin has a molecular weight of less than 2,500, there is the risk that the photosensitive resin composition may be excessively developed. Meanwhile, if the novolak resin has a molecular weight of more than 15,000, sufficient coatability of the photosensitive resin composition is not ensured and there is the risk that the photosensitive resin composition may not be developed.

Each of the alkali-soluble resins a) and b) is preferably present in an amount of 3 to 30 parts by weight, based on 100 parts by weight of the composition. The use of each resin in an amount of less than 3 parts by weight causes poor adhesion of the photosensitive resin composition to a substrate and makes it difficult to obtain uniform coatability and a desired film thickness. Meanwhile, the use of each resin in an amount exceeding 30 parts by weight makes the photosensitive resin composition too viscous. High viscosity of the photosensitive resin composition makes it impossible to obtain a smooth surface and a desired thickness of a film after coating and impedes homogeneous mixing in the preparation of a solution. Therefore, it may be difficult to achieve suitable physical properties of the photosensitive resin composition for the formation of a fine pattern.

It is desirable that the alkali-soluble resins a) and b) are mixed in a ratio of 99:1 to 30:70. Out of this range, it is not easy to achieve desired physical properties of the photosensitive resin composition in terms of heat resistance and miscibility and there is the risk that the physical properties of the photosensitive resin composition may drastically deteriorate.

The photosensitizer c) is generally called a “photoactive compound (PAC)” and serves to render the alkali-soluble resins soluble or insoluble in an alkaline developing solution. Thus, the photosensitizer is a photosensitive component that plays an important role in developing exposed and unexposed portions of the photosensitive resin composition after coating.

The photosensitizer is preferably present in an amount of 1 to 10 parts by weight, based on 100 parts by weight of the photosensitive resin composition. The use of the photosensitizer in an amount of less than 1 part by weight leads to low photosensitivity of the photosensitive resin composition. Meanwhile, the use of the photosensitizer in an amount of more than 10 parts by weight leads to deterioration in the heat resistance of the photosensitive resin composition.

Depending on the type of the photosensitizer, the exposed and unexposed portions of the photosensitive resin composition after exposure can be selectively developed with an alkaline developing solution. That is, when the solubility of the photosensitizer in an alkaline developing solution increases after exposure (positive type), the exposed portion of the photosensitive resin composition is developed. Alternatively, when the solubility of the photosensitizer in an alkaline developing solution decreases after exposure (negative type), the unexposed portion of the photosensitive resin composition is developed. In the present invention, the positive type photosensitizer is preferred.

Examples of the negative type photosensitizer include benzoin methyl ether, benzoin ethyl ether, benzoin isopropyl ether, benzoin n-butyl ether, benzoin phenyl ether, benzyl diphenyl disulfide, benzyl dimethyl ketal, anthraquinone, naphthoquinone, 3,3-dimethyl-4-methoxybenzophenone, benzophenone, p,p′-bis(dimethylamino)benzophenone, p,p′-bis(diethylamino)benzophenone, p,p′-diethylaminobenzophenone, pivalone ethyl ether, 1,1-dichloroacetophenone, p-t-butyldichloroacetophenone, a dimer of hexaarylimidazole, 2,2′-diethoxyacetophenone, 2,2′-diethoxy-2-phenylacetophenone, 2,2′-dichloro-4-phenoxyacetophenone, phenyl glyoxylate, α-hydroxyisobutylphenone, dibenzospan, 1-(4-isopropylphenyl)-2-hydroxy-2-methyl-1-propanone, 2-methyl-[4-(methylthio)phenyl]-2-morpholino-1-propanone and tribromomethylphenylsulfone. These photosensitizers are generally used alone, but may be used as a mixture of two or more thereof.

The positive type photosensitizer may be a photoacid generating photosensitizer that generates an acid by photoreaction to increase the solubility of an exposed portion in an alkaline developing solution. Specific examples of the photoacid generating photosensitizer include, but are not limited to, o-quinonediazide compounds, allyldiazonium salts, diallyliodonium salts, triallylsulfonium salts, o-nitrobenzyl esters, p-nitrobenzyl esters, trihaolmethyl s-triazine derivatives and imidosulfonate derivatives. These photoacid generating photosensitizers may be used alone or in combination of two or more thereof.

Particularly, the quinoneazide type photosensitizer is prepared by esterification of a quinonediazide with a polyphenol.

As the quinonediazide, there may be used 1,2-diazidonaphthoquinone-4-sulfonyl chloride, 1,2-diazidonaphthoquinone-5-sulfonyl chloride or 1,2-diazidonaphthoquinone-6-sulfonyl chloride. As the polyphenol, there may be used, for example, 2,3,4-trihydroxybenzophenone, 2,3,4,4′-tetrahydroxybenzophenone, 2,4-dihydroxybenzophenone, 2,3,4,3′,4′,5′-hexahydroxybenzophenone, 4,4′-(1-(4-(1-(4-hydroxyphenyl)-1-methylethyl)phenyl)ethylidene)bisphenol, bisphenol A, methyl gallate, propyl gallate, a pyrogallol-acetone condensation product, a phenol novolak resin, a m-cresol novolak resin, a p-cresol novolak resin, or a polyvinylphenol resin.

The esterification can be carried out by mixing the quinonediazide with the polyphenol in a particular molar ratio in a solvent (e.g., dioxane or acetone) and adding a catalyst (e.g., triethylamine) dropwise to the mixture. The proportion of the amino groups of the quinonediazide in the hydroxyl groups of the polyphenol is typically between 10 and 90 mol % and preferably between 40 and 80 mol %.

If needed, the photosensitive resin composition of the present invention may further comprise a sensitizer. Examples of the sensitizer include perylene, anthracene, thioxanthone, Michler's ketone, benzophenone and fluorene. Disubstituted, trisubstituted, tetrasubstituted and pentasubstituted products of the polyphenol or the quinonediazide in which some of the hydroxyl groups of the polyphenol or the amino groups of the quinonediazide are substituted with o-quinonediazidesulfonic acid may be used alone or as a mixture thereof. A substituted product of the polyphenol or the quinonediazide in which all of the hydroxyl groups of the polyphenol or the amino groups of the quinonediazide are substituted with o-quinonediazidesulfonic acid may be used.

The organic solvent d) serves to dissolve the polyimide resin, the novolak resin and the positive type photosensitizer. That is, the photosensitive resin composition of the present invention is in the form of a solution. The photosensitive resin composition of the present invention is used in the fabrication of an electrical or electronic device. The organic solvent d) enables the alkali-soluble resins and the photosensitizer to be coated on a substrate. Any organic solvent can be used without any particular limitation so long as it can uniformly dissolve the polyimide resin, the novolak resin and the photoacid generating compound and is compatible with these components. Specific examples of the organic solvent include N,N-dimethylformamide, N,N-dimethylacetamide, N-methyl-2-pyrrolidone, N-vinylpyrrolidone, dimethylsulfoxide, γ-butyrolactone and cyclohexanone.

Another organic solvent may be further used to uniformly dissolve the photosensitive resin composition according to the intended purpose, and specific examples thereof include 2-methoxyethanol, 2-ethoxyethanol, 2-butoxyethanol, 2-methoxyethyl acetate, 2-methoxy-1-propanol, 3-methoxypropyl acetate, ethyl lactate, butyl lactate, ethyl cellosolve, butyl cellosolve, ethyl carbitol, butyl carbitol, ethyl carbitol acetate, butyl carbitol acetate and ethylene glycol.

It is preferred to pass the photosensitive resin composition of the present invention through a filter (pore size=0.1-1 μm) in order to control the size of the resin particles.

The present invention also provides a method for forming an organic insulating film. Specifically, the method comprises coating the photosensitive resin composition on a substrate and curing the coated composition.

Examples of the substrate include, but are not limited to: metal substrates, such as aluminum, molybdenum, copper, ITO and chromium substrates; semiconductor films, such as silicon nitride films and amorphous silicon films; and insulating films, such as silicon oxide films and silicon nitride films. The substrate can be coated with the photosensitive resin composition by a suitable coating method, such as roll coating, spin coating, slit & spin coating or slit coating. The organic solvent can be removed by curing the coated composition to form an organic insulating film on the substrate. The organic insulating film preferably has a thickness of about 0.5 to about 3 μm. The curing is preferably performed at 80 to 130° C. for 1 to 10 min.

The present invention also provides an organic insulating film formed by the method.

The present invention also provides a method for forming a photosensitive pattern. Specifically, the method comprises a) coating the photosensitive resin composition on a substrate and pre-baking the coated composition to form an organic insulating film, and b) selectively exposing and developing the organic insulating film, followed by post-baking.

In step b), the organic insulating film is exposed using an exposure system such as a mask aligner, a stepper or a scanner. The organic insulating film is irradiated with g-line (436 nm), h-line (405 nm), i-line (365 nm) or mixed light thereof through a patterned mask. The exposure energy is determined by the performance of the alkali-soluble resins and the performance of the photosensitizer. The exposure energy is also determined by the sensitivity of the mixture of the alkali-soluble resins and the photosensitizer depending on the mixing ratio. The exposure energy is usually between 10 and 200 mJ/cm².

After completion of the exposure, the organic insulating film is developed with a developing solution by dipping, spraying and puddling to remove the exposed portion, leaving an insulating film pattern of an OLED.

The developing solution may be an aqueous solution of an inorganic alkaline compound, such as sodium hydroxide, potassium hydroxide, sodium carbonate, sodium silicate or potassium silicate, or an organic alkaline compound such as triethylamine, triethanolamine, tetramethylammonium hydroxide or tetraethylammonium hydroxide. Tetramethylammonium hydroxide is widely used in the fabrication of an electronic device to protect the metals from contamination and corrosion.

The developing solution is preferably an aqueous solution containing tetramethylammonium hydroxide in an amount of 2 to 3% by weight, based on the total weight of the developing solution. Preferably, the exposed organic insulating film is sprayed with the developing solution at 20 to 30° C. for 30 to 90 sec, cleaned with ultrapure water for 60 to 120 sec, and dried.

After the development and prior to subsequent etching, the organic insulating film pattern is post-baked to enhance the adhesion to the underlying substrate and the etching resistance. The post-baking is preferably performed at 180 to 270° C. for 10 to 30 min.

The present invention also provides a photosensitive pattern formed by the method.

The present invention also provides an electronic device comprising the organic insulating film or the photosensitive pattern.

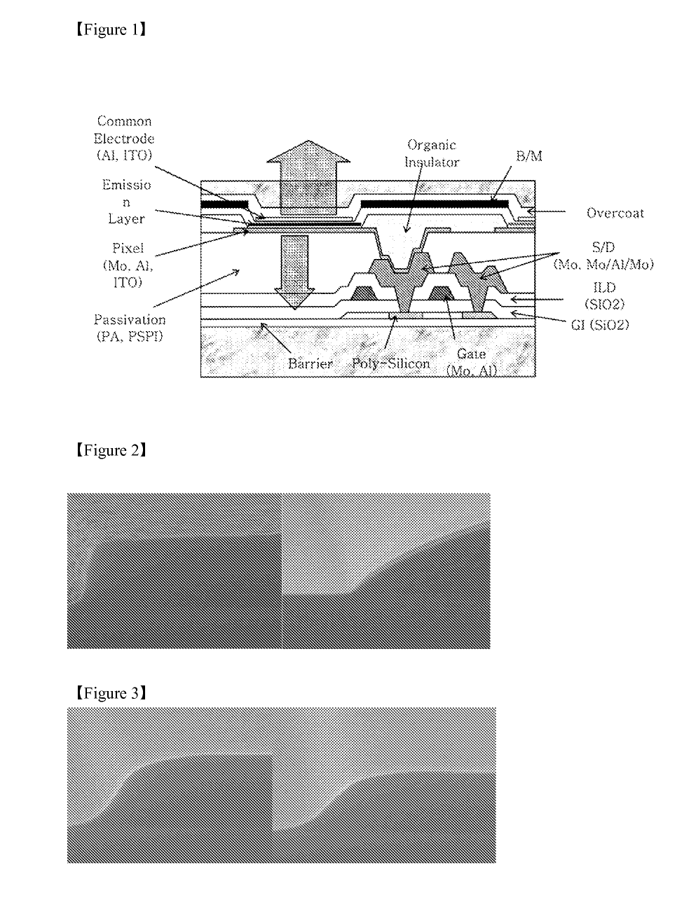

The method for producing the patterned substrate is applied to the fabrication of a variety of electronic devices. For example, the method is useful in the formation of a photosensitive pattern of an organic insulating film in an OLED (see FIG. 1).

### MODE FOR INVENTION

Hereinafter, the present invention will be explained in more detail with reference to the following examples. However, these examples are given for the purpose of illustration and are not intended to limit the present invention. In the following examples, all parts and percentages are by weight unless otherwise specified.

### EXAMPLES

### Example 1

m-Cresol and p-cresol were mixed in a weight ratio of 5:5 to prepare a novolak resin having a weight average molecular weight of 4,500 on a polystyrene basis. One mole of 2,3,4,4′-tetrahydroxybenzophenone was reacted with 3 moles of 1,2-diazidonaphthoquinone-5-sulfonyl chloride to prepare a photosensitizer. 133 g (0.30 moles) of 4,4′-hexafluoroisopropylidenediphthalic anhydride as an acid anhydride was reacted with 87 g (0.31 moles) of bis(3-amino-4-hydroxyphenyl)sulfone and 16 g (0.07 moles) of 1,3-bis(3-aminopropyl)tetramethyldisiloxane as diamines at 180° C. for 1 hr to prepare a soluble polyimide resin of Formula 2:

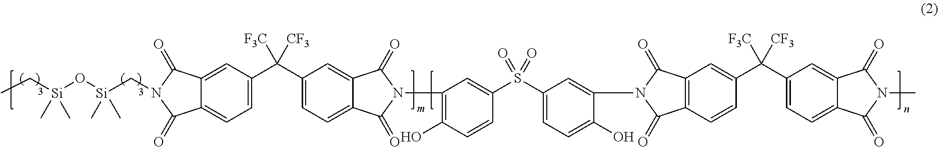

4.5 g of the novolak resin, 4 g of the photosensitizer and 13.5 g of the soluble polyimide resin were dissolved in γ-butyrolactone and ethyl lactate. The solution was filtered through a membrane (0.2 nm) to prepare a photosensitive resin composition.

### Example 2

A photosensitive resin composition was prepared in the same manner as in Example 1, except that 9 g of the novolak resin and 9 g of the polyimide resin were used.

### Example 3

A photosensitive resin composition was prepared in the same manner as in Example 1, except that 13.5 g of the novolak resin and 4.5 g of the polyimide resin were used.

### Example 4

m-Cresol and p-cresol were mixed in a weight ratio of 5:5 to prepare a novolak resin having a weight average molecular weight of 4,500 on a polystyrene basis. One mole of 2,3,4,4′-tetrahydroxybenzophenone was reacted with 3 moles of 1,2-diazidonaphthoquinone-5-sulfonyl chloride to prepare a photosensitizer. 133 g (0.30 moles) of 4,4′-hexafluoroisopropylidenediphthalic anhydride as an acid anhydride was reacted with 87 g (0.31 moles) of 3,5-diaminobenzoic acid and 13 g (0.07 moles) of 4,4′-oxydianiline as diamines at 180° C. for 1 hr to prepare a soluble polyimide resin of Formula 3:

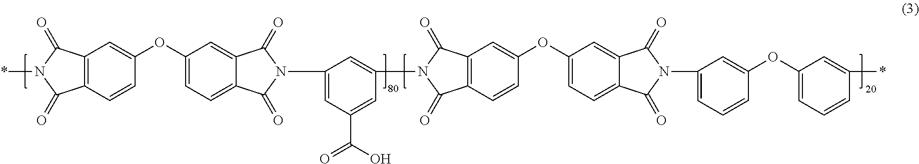

4.5 g of the novolak resin, 4 g of the photosensitizer and 13.5 g of the soluble polyimide resin were dissolved in γ-butyrolactone and ethyl lactate. The solution was filtered through a membrane (0.2 μm) to prepare a photosensitive resin composition.

### Comparative Example 1

A photosensitive resin composition was prepared in the same manner as in Example 1, except that the novolak resin was not used.

### Experimental Example 1

The photo characteristics of the photosensitive resin compositions prepared in Examples 1-4 and Comparative Example 1 and the pattern characteristics of the photosensitive resin compositions after post-baking were evaluated by the following methods. From the obtained results, the characteristics of the photosensitive resin compositions as photosensitive materials were evaluated.

1) Evaluation of Photo Characteristics

Each of the photosensitive resin compositions was spin-coated on a 4″ silicon wafer and pre-baked on a hot plate at 120° C. for 120 sec to form a 1.7 μm thick photosensitive resin film. The wafer was sequentially exposed using an I-line stepper (Nikon NSR G6) through a mask while increasing the exposure energy from 15 to 400 mJ/cm² at a rate of 10 mJ/cm². The mask had line/space patterns and circular patterns repetitively formed from 1 to 100 μm at intervals of 1 to 10 μm. The exposed wafer was developed with an aqueous solution of tetramethylammonium hydroxide (2.38 wt %) at 23° C. for 60 sec, cleaned with ultrapure water for 60 sec, and dried to form a photosensitive resin film pattern.

The point at which the pattern began to form without leaving any residue during the development was defined as a threshold energy (Eₜₕ), which is generally considered indicative of sensitivity as one of the photo characteristics of the photosensitive resin composition.

An optimum exposure energy required to transfer the same pattern as the line/space patterns (10 μm) of the mask in each of Examples 1-4 was confirmed to be 45 mJ/cm². The residual rate of the photoresist film in the unexposed portion after the development was measured to be 67%.

The threshold energy (Eₜₕ) of the photosensitive resin composition containing no novolak resin in Comparative Example 1 was 35 mJ/cm² and the residual rate of the photoresist film was 66%.

These results indicate that the presence of the novolak resin did not significantly affect the photo characteristics of the photosensitive resin compositions.

2) Evaluation of Lateral Angles of Patterns Before and after Post-Baking

Each of the photosensitive resin compositions prepared in Examples 1-4 and Comparative Example 1 was spin-coated on a 4″ silicon wafer and a 4″ silicon wafer having a silicon nitride film (1,000 Å) deposited thereon, and pre-baked on a hot plate at 120° C. for 120 sec to form 1.3 μm thick organic insulating films. Each of the wafers was exposed using an I-line stepper (Nikon NSR G6) at 45 mJ/cm², which was determined to be the optimum exposure energy in the evaluation of photo characteristics, through a mask. The mask had line/space patterns and circular patterns repetitively formed from 1 to 100 μm at intervals of 1 to 10 μm. The exposed wafer was developed with an aqueous solution of tetramethylammonium hydroxide (2.38 wt %) at 23° C. for 60 sec, cleaned with ultrapure water for 60 sec, and dried to form an organic insulating film pattern. Subsequently, the pattern was subjected to post-baking at 230° C. for 10 min.

The cross section of the post-baked wafer was observed using a field emission scanning electron microscope (FE-SEM) to evaluate how much the pattern flowed down depending on the presence or absence of the novolak resin.

Changes in the lateral angle of the pattern before and after post-baking are shown in Table 1.

TABLE 1

| | | | | | Physical properties | |
|---|---|---|---|---|---|---|
| | Components (wt %) | | | | Lateral angles (°) of pattern | |
| | Alkali-soluble | Alkali-soluble | | Organic | Before | After |
| Example No. | resin ^{A)} | resin ^{B)} | Photosensitizer ^{C)} | solvent ^{D)} | post-baking | post-baking |
| Ex. 1 | 13.5 | 4.5 | 4 | 77.8 | 90 | 35 |
| Ex. 2 | 9 | 9 | 4 | 77.8 | 90 | 50 |
| Ex. 3 | 4.5 | 13.5 | 4 | 77.8 | 90 | 65 |
| Ex. 4 | 13.5 | 4.5 | 4 | 77.8 | 90 | 35 |
| Comp. Ex. 1 | 18 | 0 | 4 | 77.8 | 47 | 42 |

Note)
^{A)} Alkali-soluble polyimide resin
^{B)} Novolak resin, weight average molecular weight = 4,500, m-cresol/p-cresol = 5/5
^{C)} A reaction product of 1 mole of 2,3,4,4′-tetrahydroxybenzophenone and 3, 3.5 or 2 moles of 1,2-diazidonaphthoquinone-5-sulfonyl chloride
^{D)} A mixture of γ-butyrolactone (GBL) and ethyl lactate (EL)

FIG. 2 shows micrographs of a lateral side of the patterned organic insulating film formed using the photosensitive resin composition of Example 1, taken before and after post-baking. FIG. 3 shows micrographs of a lateral side of the patterned organic insulating film formed using the photosensitive resin composition of Comparative Example 1, taken before and after post-baking.

The micrographs of FIGS. 2 and 3 show that the use of the photosensitive resin composition of Example 1 markedly decreased the lateral angle of the patterned organic insulating film after post-baking.

1. A photosensitive resin composition comprising
a) 3 to 30 parts by weight of an alkali-soluble polyimide resin,
b) 3 to 30 parts by weight of an alkali-soluble novolak resin,
c) 1 to 10 parts by weight of a photosensitizer, and
d) 59 to 93 parts by weight of an organic solvent.

2. The photosensitive resin composition of claim 1, wherein the alkali-soluble polyimide resin a) is represented by Formula 1: 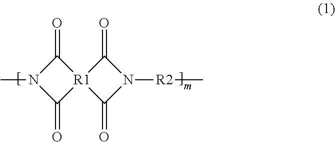
wherein m is an integer from 3 to 10,000, R¹ is a tetravalent organic group, and R² is a divalent organic group, with the proviso that 5 to 100 mol % of R² is fluorinated.

3. The photosensitive resin composition of claim 1, wherein the alkali-soluble novolak resin b) has a weight average molecular weight of 2,500 to 15,000.

4. The photosensitive resin composition of claim 1, wherein the photosensitizer c) is prepared by esterification of a quinonediazide with a polyphenol.

5. The photosensitive resin composition of claim 1, wherein the organic solvent d) is selected from the group consisting of ketones, glycol ethers, acetates and mixtures thereof.

6. The photosensitive resin composition of claim 1, wherein the photosensitive resin composition is passed through a filter having a pore size of 0.1-1 μm.

7. The photosensitive resin composition of claim 1, wherein the alkali-soluble resins a) and b) are mixed in a ratio of 99:1 to 30:70.

8. A method for forming an organic insulating film, the method comprising coating the photosensitive resin composition of claim 1 on a substrate and curing the coated composition.

9. The method of claim 8, wherein the substrate is a metal substrate, a semiconductor film or an insulating film.

10. The method of claim 8, wherein the composition is coated to a thickness of 1 to 3 μm.

11. The method of claim 8, wherein the curing is performed at 90 to 130° C. for 1 to 5 min.

12. A method for forming a photosensitive pattern, the method comprising
a) coating the photosensitive resin composition of claim 1on a substrate and pre-baking the coated composition to form an organic insulating film, and
b) selectively exposing and developing the organic insulating film, followed by post-baking.

13. The method of claim 12, wherein the substrate is a metal substrate, a semiconductor film or an insulating film.

14. The method of claim 12, wherein the organic insulating film has a thickness of 1 to 3 μm.

15. The method of claim 12, wherein the exposure is performed with an energy of 10 to 200 mJ/cm².

16. The method of claim 12, wherein the post-baking is performed at 180 to 250° C. for 5 to 30 min.
